(19) United States
(12) Patent Application Publication
(10) Pub. No.: US 2026/0292408 A1
(43) Pub. Date: Sep. 24, 2026

(54) Lithium Niobate MEMS Microphone

(71) Applicant: Silicon Audio, Inc., Austin, TX (US)

(72) Inventors: Xiaoyu Niu, Austin, TX (US); Neal A. Hall, Austin, TX (US)

(21) Appl. No.: 19/287,303

(22) Filed: Jul. 31, 2025

Related U.S. Application Data
(60) Provisional application No. 63/774,551, filed on Mar. 19, 2025.

(51) Int. Cl. H04R 17/02; H04R 7/06; H10N 30/853

(52) U.S. Cl. CPC H04R 17/02; H04R 7/06; H10N 30/8542; H04R 2201/003

(57) ABSTRACT

A microphone can include a multilayer lithium niobate (LN) diaphragm for use in sensing a lateral in-plane electric field resulting from out-of-plane deformation due to acoustic pressure, e.g., the multilayer LN diaphragm can produce an in-plane electric field when subjected to an out-of-plane pressure or force, e.g., such as acoustic pressure.

### PRIORITY DATA

This application claims benefit of priority to U.S. Provisional Application Ser. No. 63/774,551, titled “Lithium Niobate MEMS Microphone”, filed Mar. 19, 2025, which is hereby incorporated by reference in its entirety as though fully and completely set forth herein.

### FIELD OF THE INVENTION

This disclosure relates generally to microphones, and more particularly to lithium niobate micro-electro-mechanical systems (MEMS) microphones for use in sensing a lateral in-plane electric field resulting from out-of-plane deformation due to acoustic pressure.

### DESCRIPTION OF THE RELATED ART

Miniature microphones, which may be used in a variety of applications (e.g., ultrasonic transducers, sound localization, gas sensors, hydrophone, quench detection, cellular telephones, laptop computers, portable consumer electronics, hearing aids), generally include a compliant membrane and a rigid back electrode in close proximity to form a capacitor with a gap. Incoming sound waves induce vibrations in the compliant membrane and these vibrations change the capacitance of the structure which can be sensed with electronics.

Recently, MEMS processing has been utilized to fabricate miniature microphones. As MEMS processing has developed, a pursuit for increased signal-to-noise-ratio (SNR) via optimization of conventional capacitive MEMS microphones, optical MEMS microphones, dual diaphragm capacitive MEMS microphones, and piezoelectric MEMS microphones has been a main focus of development. Among these various implementations, MEMS piezoelectric microphones are not typically considered for high SNR applications, however, continuous advances in materials may make it possible to build piezoelectric MEMS microphones for high SNR applications. However, further improvements in the field are desired.

### SUMMARY OF THE INVENTION

Various embodiments of a microphone are presented herein. The microphone can include a multilayer lithium niobate (LN) diaphragm for use in sensing a lateral in-plane electric field resulting from out-of-plane deformation due to acoustic pressure, e.g., the multilayer LN diaphragm can produce an in-plane electric field when subjected to an out-of-plane pressure or force, e.g., such as acoustic pressure.

For example, in some embodiments, a microphone can include an LN diaphragm that can be configured to deform under pressure. The LN diaphragm can include multiple layers of LN crystal wafers. A first layer of LN crystal wafer can have a first polarization and a second layer of LN crystal can have a second polarization opposite the first polarization. The first layer can be bonded to the second layer to form the LN diaphragm such that the LN diaphragm is configured to generate and/or produce an in-plane electrical field in a single direction upon out-of-plane deformation, e.g., an in-plane electrical field in the first layer of LN crystal is in a same direction as an in-plane electrical field in the second layer of LN crystal. In addition, the microphone can include at least two electrodes positioned on a first surface of the LN diaphragm. The LN diaphragm can be positioned on top of a substrate, e.g., the substrate can be on a second surface of the LN diaphragm. The substrate can include a cavity under the LN diaphragm, e.g., a backside cavity, to allow the LN diaphragm to deform out-of-plane due to a pressure imbalance between the first surface and second surface of the LN diaphragm.

As another example, in some embodiments, a microphone package, e.g., suitable for integration into a product, can include a first substrate that houses a microphone die and an Application Specific Integrated Circuit (ASIC). The first substrate can have and/or include a sound inlet. The microphone package can further include a cavity formed by a second substrate and sidewalls. The sound inlet can allow one or more deformable elements to be in contact with and deform under external pressure and pressure gradient from a sound field external to the microphone package. Signals from sensing ports, e.g., formed via a sensing material in contact with the deformable elements can be routed to the ASIC and signals from the ASIC can be routed to the first substrate and/or the second substrate via wiring. Vertical Interconnect Accesses (VIAs) in the first substrate and/or the second substrate can make electrical signals available at an external surface of the microphone package. The one or more deformable elements can be or include an LN diaphragm.

### BRIEF DESCRIPTION OF THE DRAWINGS

The following detailed description refers to the accompanying drawings, which are now briefly described.

FIGS. 1A-1C illustrate examples of a packaged microphone, according to some embodiments.

FIG. 2 illustrates a cross-sectional view of a packaged microphone, according to some embodiments.

FIGS. 3A and 3B illustrate examples of a MEMS die, according to some embodiments.

FIG. 4A illustrates another example of a MEMS die, according to some embodiments.

FIG. 4B illustrates an example of a MEMS die, according to some embodiments.

FIGS. 5A and 5B illustrate laser Doppler vibrometer characterization of an example LN MEMS microphone, according to some embodiments.

FIG. 5C illustrates admittance characterization of an example LN MEMS microphone, according to some embodiments.

FIGS. 6A-6C illustrate an example of a microphone device under test (DUT) package, according to some embodiments.

FIG. 7 illustrates an example of modeling used to predict sensitivity and noise floor of an LN microphone, according to some embodiments.

FIGS. 8A-8C illustrate an example of an acoustic measurement of an LN MEMS microphone, according to some embodiments.

FIG. 9 illustrates an example of one possible design of an LN MEMS microphone, according to some embodiments.

FIGS. 10A-10D illustrate example simulation results of a modeled LN MEMS microphone, according to some embodiments.

FIGS. 11A-11C illustrate an example of a user equipment device (UE) 700 which can include embodiments of the invention.

While the invention is susceptible to various modifications and alternative forms, specific embodiments thereof are shown by way of example in the drawings and are herein described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

The headings used herein are for organizational purposes only and are not meant to be used to limit the scope of the description. As used throughout this application, the word “can” and “may” are used in a permissive sense (i.e., meaning having the potential to), rather than the mandatory sense (i.e., meaning must). The words “include,” “including,” and “includes” indicate open-ended relationships and therefore mean including, but not limited to. Similarly, the words “have,” “having,” and “has” also indicated open-ended relationships, and thus mean having, but not limited to. The terms “first,” “second,” “third,” and so forth as used herein are used as labels for nouns that they precede, and do not imply any type of ordering (e.g., spatial, temporal, logical, etc.) unless such an ordering is otherwise explicitly indicated. For example, a “third component electrically connected to the module substrate” does not preclude scenarios in which a “fourth component electrically connected to the module substrate” is connected prior to the third component, unless otherwise specified. Similarly, a “second” feature does not require that a “first” feature be implemented prior to the “second” feature, unless otherwise specified.

Various components may be described as “configured to” perform a task or tasks. In such contexts, “configured to” is a broad recitation generally meaning “having structure that” performs the task or tasks during operation. As such, the component can be configured to perform the task even when the component is not currently performing that task (e.g., a set of electrical conductors may be configured to electrically connect a module to another module, even when the two modules are not connected). In some contexts, “configured to” may be a broad recitation of structure generally meaning “having circuitry that” performs the task or tasks during operation. As such, the component can be configured to perform the task even when the component is not currently on. In general, the circuitry that forms the structure corresponding to “configured to” may include hardware circuits.

Various components may be described as performing a task or tasks, for convenience in the description. Such descriptions should be interpreted as including the phrase “configured to.” Reciting a component that is configured to perform one or more tasks is expressly intended not to invoke 35 U.S.C. § 112(f) for that component.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

### DETAILED DESCRIPTION OF THE INVENTION

### Terms

Approximately—refers to a value that is almost correct or exact. For example, approximately may refer to a value that is within 1 to 10 percent of the exact (or desired) value. It should be noted, however, that the actual threshold value (or tolerance) may be application dependent. For example, in one embodiment, “approximately” may mean within 0.1% of some specified or desired value, while in various other embodiments, the threshold may be, for example, 2%, 3%, 5%, and so forth, as desired or as required by the particular application. Furthermore, the term approximately may be used interchangeably with the term substantially. In other words, the terms approximately and substantially are used synonymously to refer to a value, or shape, that is almost correct or exact.
Couple—refers to the combining of two or more elements or parts. The term “couple” is intended to denote the linking of part A to part B, however, the term “couple” does not exclude the use of intervening parts between part A and part B to achieve the coupling of part A to part B. For example, the phrase “part A may be coupled to part B” means that part A and part B may be linked indirectly, e.g., via part C. Thus, part A may be connected to part C and part C may be connected to part B to achieve the coupling of part A to part B.
Functional Unit (or Processing Element)—refers to various elements or combinations of elements. Processing elements include, for example, circuits such as an ASIC (Application Specific Integrated Circuit), portions or circuits of individual processor cores, entire processor cores, individual processors, programmable hardware devices such as a field programmable gate array (FPGA), and/or larger portions of systems that include multiple processors, as well as any combinations thereof.
User Equipment (UE) (or “UE Device”)—any of various types of computer systems or devices that are mobile or portable, and that perform wireless communications. Examples of UE devices include mobile telephones or smart phones (e.g., iPhone™, Android™-based phones), tablet computers, portable gaming devices, laptops, wearable devices (e.g., smart watch, smart glasses, smart goggles, head-mounted display devices, and so forth), portable Internet devices, music players, data storage devices, or other handheld devices, automobiles and/or motor vehicles, unmanned aerial vehicles (UAVs) (e.g., drones), UAV controllers (UACs), etc. In general, the term “UE” or “UE device” can be broadly defined to encompass any electronic, computing, and/or telecommunications device (or combination of devices) which is easily transported by a user and capable of wireless communication.
Wireless Device or Station (STA)—any of various types of computer systems or devices that perform wireless communications. A wireless device can be portable (or mobile) or can be stationary or fixed at a certain location. The terms “station” and “STA” are used similarly. A UE is an example of a wireless device.
Communication Device—any of various types of computer systems or devices that perform communications, where the communications can be wired or wireless. A communication device can be portable (or mobile) or can be stationary or fixed at a certain location. A wireless device is an example of a communication device. A UE is another example of a communication device.
Processing Element (or Processor)—refers to various elements or combinations of elements that are capable of performing a function in a device, e.g., in a communication device or in a network infrastructure device. Processors can include, for example: processors and associated memory, circuits such as an ASIC (Application Specific Integrated Circuit), portions or circuits of individual processor cores, entire processor cores, processor arrays, programmable hardware devices such as a field programmable gate array (FPGA), and/or larger portions of systems that include multiple processors, as well any of various combinations of the above.
Piezoelectric sensor—refers to a sensor that relies on the piezoelectric effect, i.e., the electromechanical interaction between the mechanical and the electrical state in a certain class of materials.
Audio Spectrum—refers to the portion of the frequency spectrum that is audible to humans. In general, audible frequencies range from approximately 20 Hz on the low end to 20,000 Hz on the high end. Thus, the audio spectrum is considered to span from 20 Hz to 20 kHz. In general, the center of the audio spectrum may be considered to be approximately 1 kHz.

### LN MEMS Microphone

In current implementations, MEMS processing has been utilized to fabricate miniature microphones. As MEMS processing has developed, a pursuit for increased signal-to-noise-ratio (SNR) via optimization of conventional capacitive MEMS microphones, optical MEMS microphones, dual diaphragm capacitive MEMS microphones, and piezoelectric MEMS microphones has been a main focus of development. Among these various implementations, MEMS piezoelectric microphones are not typically considered for high SNR applications, however, continuous advances in materials may make it possible to build piezoelectric MEMS microphones for high SNR applications. Therefore, further improvements are desired.

Embodiments described herein provide systems and mechanisms for a high SNR MEMS microphone. For example, such a microphone can include a multilayer lithium niobate (LN) diaphragm for use in sensing a lateral in-plane electric field resulting from out-of-plane deformation due to acoustic pressure, e.g., the multilayer LN diaphragm can produce an in-plane electric field when subjected to an out-of-plane pressure or force, e.g., such as acoustic pressure. In other words, the LN diaphragm can be configured to deform under pressure. The LN diaphragm can include multiple layers of LN crystal wafers. A first layer of LN crystal wafer can have a first polarization and a second layer of LN crystal can have a second polarization opposite the first polarization. The first layer can be bonded to the second layer to form the LN diaphragm such that the LN diaphragm is configured to generate and/or produce an in-plane electrical field in a single direction upon out-of-plane deformation, e.g., an in-plane electrical field in the first layer of LN crystal is in a same direction as an in-plane electrical field in the second layer of LN crystal. In addition, the microphone can include at least two electrodes positioned on a first surface of the LN diaphragm. The LN diaphragm can be positioned on top of a substrate, e.g., the substrate can be on a second surface of the LN diaphragm. The substrate can include a cavity under the LN diaphragm, e.g., a backside cavity, to allow the LN diaphragm to deform out-of-plane due to a pressure imbalance between the first surface and second surface of the LN diaphragm.

As another example, a microphone package, e.g., suitable for integration into a product, can include a first substrate that houses a microphone die and an Application Specific Integrated Circuit (ASIC). The first substrate can have and/or include a sound inlet. The microphone package can further include a cavity formed by a second substrate and sidewalls. The sound inlet can allow one or more deformable elements to be in contact with and deform under external pressure and pressure gradient from a sound field external to the microphone package. Signals from sensing ports, e.g., formed via a sensing material in contact with the deformable elements can be routed to the ASIC and signals from the ASIC can be routed to the first substrate and/or the second substrate via wiring. Vertical Interconnect Accesses (VIAs) in the first substrate and/or the second substrate can make electrical signals available at an external surface of the microphone package. The one or more deformable elements can be or include an LN diaphragm.

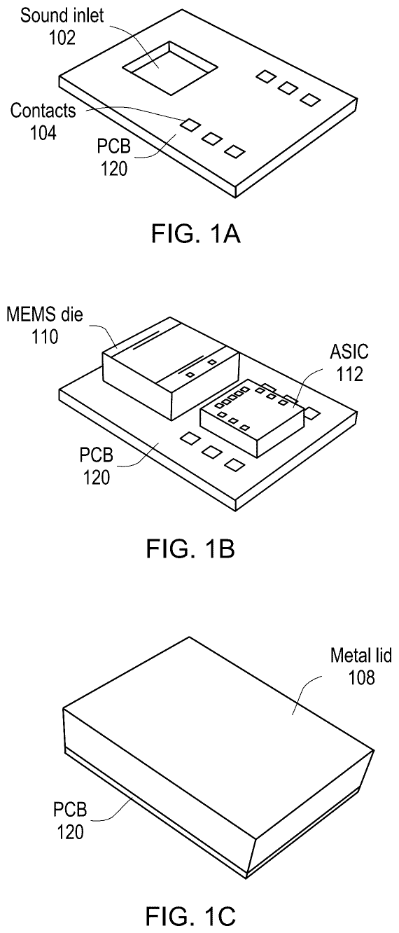

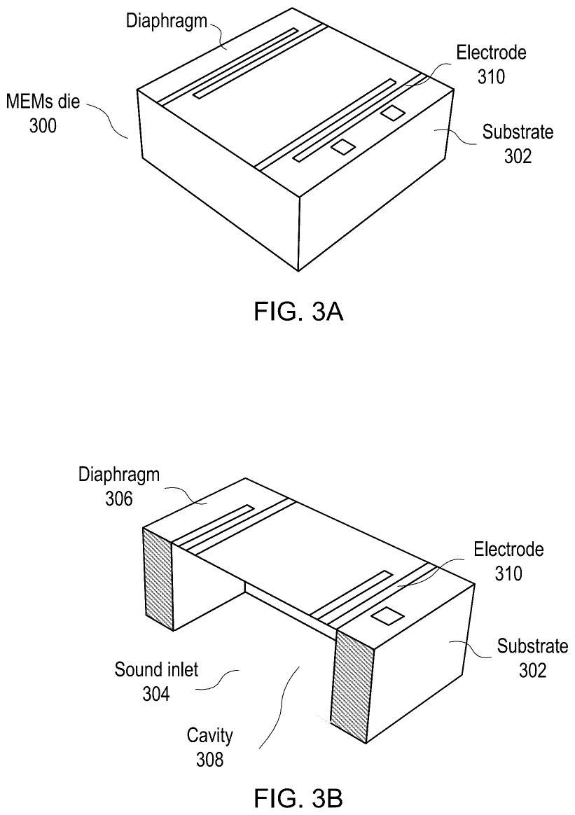

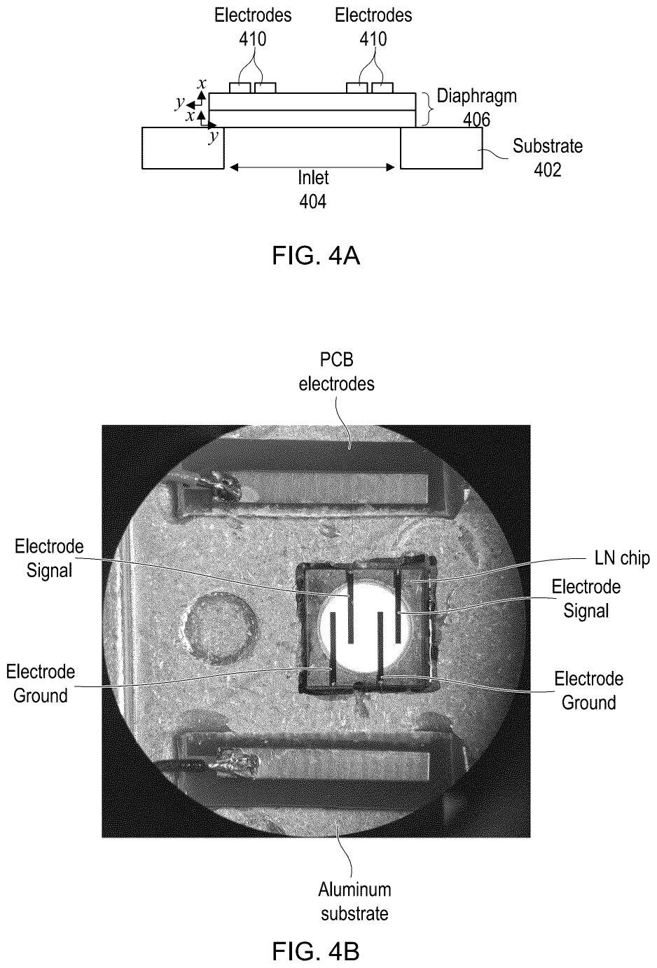

FIGS. 1A-1C illustrate examples of a packaged microphone, according to some embodiments. The packaged microphone, at least in some instances, can include a MEMS microphone that includes a multilayer LN diaphragm. As shown in FIG. 1A, the packaged microphone can include a printed circuit board (PCB) 120 with an inlet hole (e.g., a sound inlet) 102 and contacts 104 to receive wire bonds. This PCB can be configured as a “bottom” substrate of the microphone package. FIG. 1B illustrates an example of a PCB, such as the PCB 120 illustrated in FIG. 1A, with a MEMS microphone die 110 and application specific integrated circuit (ASIC) 112 mounted on it. The MEMS microphone die 110 can be a MEMS microphone 300 as described below in reference to FIGS. 3A, 3B, and 4. For example, the MEMS microphone 110 can include a multilayer LN diaphragm configured to produce an in-plane electric field when subjected to an out-of-plane pressure or force, e.g., such as acoustic pressure. In other words, the LN diaphragm can be configured to deform under pressure. The LN diaphragm can include multiple layers of LN crystal wafers. A first layer of LN crystal wafer can have a first polarization and a second layer of LN crystal can have a second polarization opposite the first polarization. The first layer can be bonded to the second layer to form the LN diaphragm such that the LN diaphragm is configured to generate and/or produce an in-plane electrical field in a single direction upon out-of-plane deformation, e.g., an in-plane electrical field in the first layer of LN crystal is in a same direction as an in-plane electrical field in the second layer of LN crystal. In addition, the MEMS microphone can include at least two electrodes positioned on a first surface of the LN diaphragm. The LN diaphragm can be positioned on top of a substrate, e.g., the substrate can be on a second surface of the LN diaphragm. The substrate can include a cavity under the LN diaphragm, e.g., a backside cavity, to allow the LN diaphragm to deform out-of-plane due to a pressure imbalance between the first surface and second surface of the LN diaphragm. FIG. 1C illustrates a lid 108 on a PCB, such as the PCB 120 illustrated in FIGS. 1A and 1B.

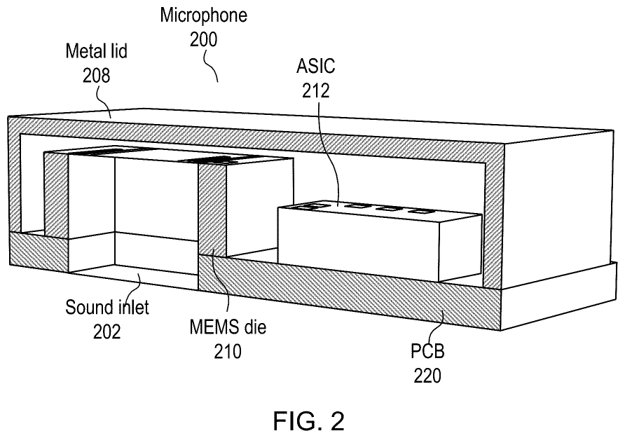

FIG. 2 illustrates a cross-sectional view of a packaged microphone, according to some embodiments. The packaged microphone 200, at least in some instances, can include a MEMS microphone (or MEMS die) 210 that includes a multilayer LN diaphragm, e.g., as described above in reference to FIGS. 1A, 1B, and 1C. As shown, the package microphone 200 can include a lid, e.g., a metal lid 208, an ASIC 212, a PCB 220, a MEMS die 210, and a sound inlet 202. The MEMS die 210 can be positioned on top of the sound inlet 202. The MEMS die 210 can be a MEMS microphone (or MEMS die) 300 as described below in reference to FIGS. 3A, 3B, and 4. For example, the MEMS die 210 can include a multilayer LN diaphragm configured to produce an in-plane electric field when subjected to an out-of-plane pressure or force, e.g., such as acoustic pressure. In other words, the LN diaphragm can be configured to deform under pressure. The LN diaphragm can include multiple layers of LN crystal wafers. A first layer of LN crystal wafer can have a first polarization and a second layer of LN crystal can have a second polarization opposite the first polarization. The first layer can be bonded to the second layer to form the LN diaphragm such that the LN diaphragm is configured to generate and/or produce an in-plane electrical field in a single direction upon out-of-plane deformation, e.g., an in-plane electrical field in the first layer of LN crystal is in a same direction as an in-plane electrical field in the second layer of LN crystal. In addition, the MEMS die can include at least two electrodes positioned on a first surface of the LN diaphragm. The LN diaphragm can be positioned on top of a substrate, e.g., the substrate can be on a second surface of the LN diaphragm. The substrate can include a cavity under the LN diaphragm, e.g., a backside cavity, to allow the LN diaphragm to deform out-of-plane due to a pressure imbalance between the first surface and second surface of the LN diaphragm.

FIGS. 3A and 3B illustrate examples of a MEMS die, according to some embodiments. In particular, FIG. 3A illustrates a full view of a MEMS die (or MEMS microphone) 300 and FIG. 3B illustrates a cross section view of a MEMS die 300. As shown, the MEMS die 300 can include a substrate 302 with a sound inlet 304, a diaphragm 306 positioned over the sound inlet 304 on the substrate 302 to create a cavity 308, and one or more electrodes 310 positioned on a surface of the diaphragm 306 that is opposite of a surface of the diaphragm in contact with the substrate 302. The diaphragm 306 can be a lithium niobate (LN) diaphragm, at least in some instances. In some instances, the LN diaphragm can be a multilayer LN diaphragm configured to produce an in-plane electric field when subjected to an out-of-plane pressure or force, e.g., such as acoustic pressure. In other words, the LN diaphragm can be configured to deform under pressure. The LN diaphragm can include multiple layers of LN crystal wafers. A first layer of LN crystal wafer can have a first polarization and a second layer of LN crystal can have a second polarization opposite the first polarization. The first layer can be bonded to the second layer to form the LN diaphragm such that the LN diaphragm is configured to generate and/or produce an in-plane electrical field in a single direction upon out-of-plane deformation, e.g., an in-plane electrical field in the first layer of LN crystal is in a same direction as an in-plane electrical field in the second layer of LN crystal. As noted, the one or more electrodes can be positioned on a first surface of the LN diaphragm and the LN diaphragm can be positioned on top of the substrate above the sound inlet, e.g., the substrate can be on a second surface of the LN diaphragm, e.g., to form a cavity under the LN diaphragm, e.g., a backside cavity, to allow the LN diaphragm to deform out-of-plane due to a pressure imbalance between the first surface and second surface of the LN diaphragm.

FIG. 4A illustrates another example of a MEMS die, according to some embodiments. As shown, a MEMS die 400, which can be an example of the MEMS die 300 described in reference to FIGS. 3A-3C, can include a substrate 402 with an inlet cutout 404, a multilayer diaphragm 406 positioned on the substrate 402 and over the inlet cutout 404, and at least two electrodes 410 positioned on a surface of the multilayer diaphragm 406 opposite a surface of the multilayer diaphragm 406 positioned on the substrate 402. The multilayer diaphragm 406 can be a multilayer lithium niobate (LN) diaphragm, at least in some instances. The multilayer LN diaphragm can be configured to produce an in-plane electric field when subjected to an out-of-plane pressure or force, e.g., such as acoustic pressure. In other words, the multilayer LN diaphragm can be configured to deform under pressure. The multilayer LN diaphragm can include multiple layers of LN crystal wafers. A first layer of LN crystal wafer can have a first polarization and a second layer of LN crystal can have a second polarization opposite the first polarization. The first layer can be bonded to the second layer to form the LN diaphragm such that the multilayer LN diaphragm is configured to generate and/or produce an in-plane electrical field in a single direction upon out-of-plane deformation, e.g., an in-plane electrical field in the first layer of LN crystal is in a same direction as an in-plane electrical field in the second layer of LN crystal. As noted, the at least two electrodes can be positioned on a first surface of the multilayer LN diaphragm and the multilayer LN diaphragm can be positioned on top of the substrate above the sound inlet, e.g., the substrate can be on a second surface of the multilayer LN diaphragm, e.g., to form a cavity under the LN diaphragm, e.g., a backside cavity, to allow the multilayer LN diaphragm to deform out-of-plane due to a pressure imbalance between the first surface and second surface of the multilayer LN diaphragm.

FIG. 4B illustrates an example of a MEMS die, according to some embodiments. In particular, FIG. 4B illustrates an LN chip clamped on an aluminum substrate with a circular hole opening. A wafer bonding process can integrate two individual layers of LN with opposite polarization to form a dual layer diaphragm (a bimorph LN diaphragm), e.g., as described above in reference to FIG. 4A. Metal deposition and patterning can generate one or more electrodes on the top of the bimorph LN diaphragm, as shown. Note that a singulated 8 mm by 8 mm bimorph LN chip can be obtained via dicing of the dual layer substrate, a singulated 8 mm×8 mm bimorph LN chips are obtained. In more detail, a hole can be drilled on an aluminum substrate and an epoxy can secure the bimorph LN chip on the circular hole, resulting in a circular LN diaphragm. Wire bonds can route signals from the bimorph LN chip to printed circuit board (PCB) electrodes and soldered connections to the PCB electrodes can enable signal readout and/or application of actuation voltage signals to the bimorph LN diaphragm. Note that a single layer of LN would not work in this flexural configuration because the neutral bending axis of a diaphragm is at its center. Thus, stress above the neutral axis is of opposite polarity to stress below the neutral axis and similarly, electric fields above and below the neutral axis would also be of opposing polarity. The use of two layers, opposite in their polarization, ensures that the electric fields in the plane of the two layers are aligned in the same direction. This enables the signal energy in both layers, top and bottom, to be transduced by electrodes positioned on the top surface.

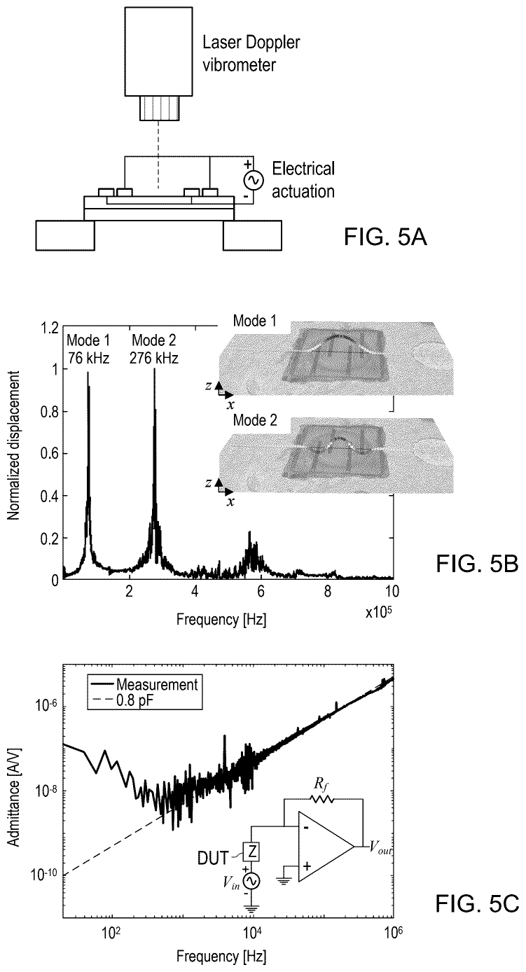

FIGS. 5A through 10D illustrate further aspects of an LN MEMS microphone according to the embodiments described herein. For example, FIGS. 5A and 5B illustrate laser Doppler vibrometer characterization of an example LN MEMS microphone. FIG. 5C illustrates admittance characterization of an example LN MEMS microphone. As shown in FIG. 5A, an LN diaphragm device, e.g., such as the LN diaphragms/MEMS dies/microphones as described herein, is mounted underneath a laser Doppler vibrometer (LDV). A broad band chirp voltage is applied to the LN diaphragm and the resulting lateral electrical field vibrates the LN diaphragm while the LDV measures and records diaphragm displacement. FIG. 5B illustrates center displacement frequency response of the LN diaphragm. The inset images show line measurement for first mode and second mode vibration, respectively. In particular, FIG. 5B illustrates the many small spurious mode resonances caused by the mounting, specifically the high model density of the coupled system, e.g., diaphragm plus epoxy plus the aluminum substrate. The LDV measurements, however, confirm that the diaphragm and electrodes are in working order.

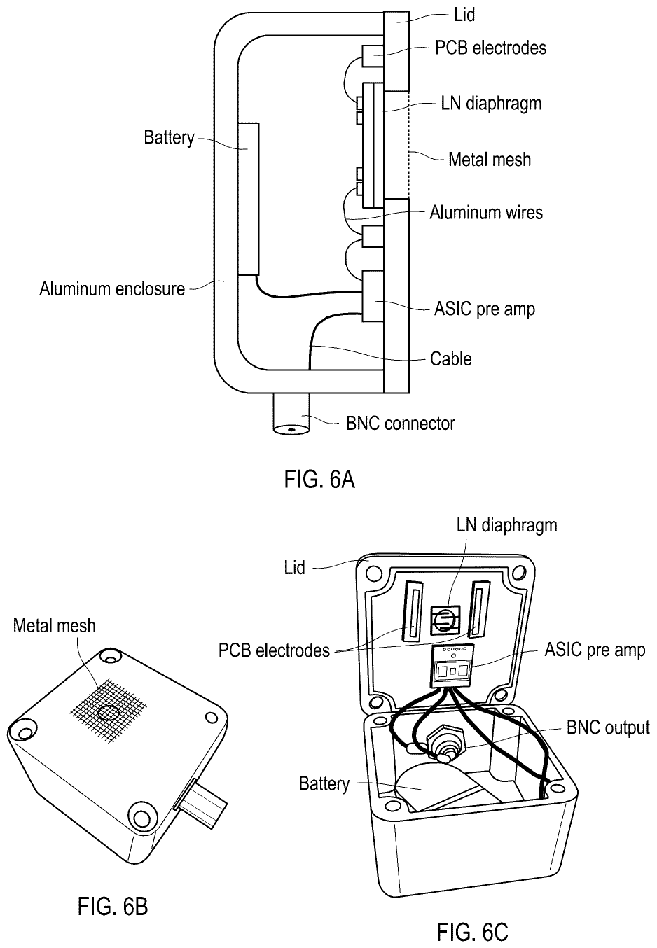

FIGS. 6A-6C illustrate an example of a microphone device under test (DUT) package. In particular, FIG. 6A illustrates an example of a schematic showing a DUT package of an LN microphone and FIGS. 6B and 6C illustrates photos of a DUT package with lid open (FIG. 6C) and lid closed (FIG. 6B). In more detail, to facilitate acoustic testing, it is necessary to connect an LN diaphragm to a high input impedance pre-amplifier with low output impedance. Thus, as illustrated, integrated circuit (IC) pre-amplifier (e.g., an ASIC pre-amp) is connected to an LN chip and PCB electrodes are used as interconnection instead of directly wire bonding from the LN diaphragm to the pre-amplifier. Such interconnections allow testing of the LN diaphragm and amplifier separately, making debugging easier. Further, to shield against electromagnetic interference (EMI), a battery is included inside the enclosure and the opening is covered with a metal mesh, which is acoustically transparent. Electrical signals originate at the LN diaphragm, are then routed to the IC pre-amplifier, and are then routed out of the package using the BNC connector.

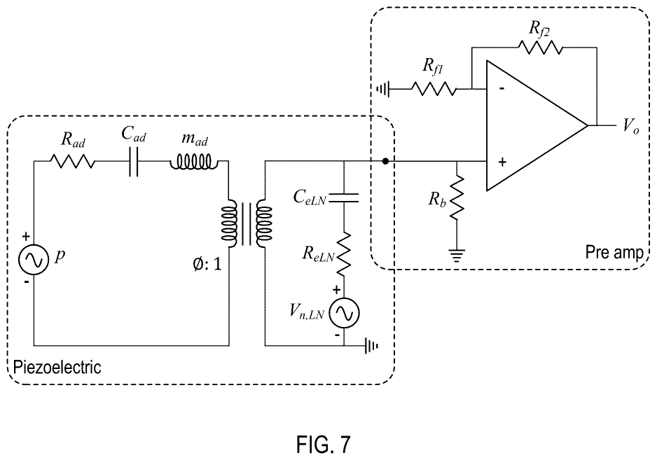

FIG. 7 illustrates an example of modeling used to predict sensitivity and noise floor of an LN microphone. In particular, FIG. 7 illustrates an example of a lumped model of the example DUT package described in reference to FIGS. 6A-C. Piezoelectric transduction is represented within the lower left dashed line and pre-amp transduction is represented within the upper right dashed line. Since the example DUT package back volume and inlet hole are large, the effect of back cavity compliance and inlet port radiation can be neglected. Thus, the transducer model comprises only the LN diaphragm. R_{ad}, C_{ad}, and m_{ad} are the acoustical resistance, compliance, and mass of the LN diaphragm. C_{eLN} and R_{eLN} are the electrical capacitance and series electrical resistance of the LN diaphragm. The acoustical mass and compliance are obtained using an FEA model. The acoustical resistance is extracted from LDV measurements. The measured quality factor is Q(=100). Q=(2πf₀m_{ad})/R_{ad} is used to derive R_{ad}. R_{eLN} is from dielectric loss of the LN material and is equal to the square root of (tan δ/(ωC_{eLN}) where tan δ is the dielectric loss coefficient and ω is angular frequency. For this bimorph LN chip, tan δ=0.003. Note that the value of the loss tangent can be strongly influenced by the wafer bonding process. The transform ratio φ is defined as the short circuit charge per volumetric displacement of the diaphragm, with units of [C/m³]. This parameter is also obtained from FEA. As noted, the upper right dashed line describes the effective model of the pre-amplifier. The pre-amplifier has 6 dB gain across the audio bandwidth (e.g., 20-20,000 Hz). A large bias resistor (R_{b}) of 1 TΩ results in low noise for the pre-amplifier throughout the audio bandwidth. The dominant noise for this system is dielectric loss induced in the LN film. Note that there is almost no parasitic capacitance between the piezoelectric transducer and the pre-amplifier as only free suspended wires make connection between the two. Sensitivity can be modeled by shorting noise source V_{n,LN} and setting input acoustic pressure p=1 [Pa]. Similarly, output noise can be simulated by shorting the pressure source. Across the audio bandwidth, simulated sensitivity and noise show good agreement with measurements. Small peaks in the noise measurement below 100 Hz come from 60 Hz EMI. Noise can be input-referred to acoustic pressure, A-weighted (A-wt) and integrated to obtain A-wt noise.

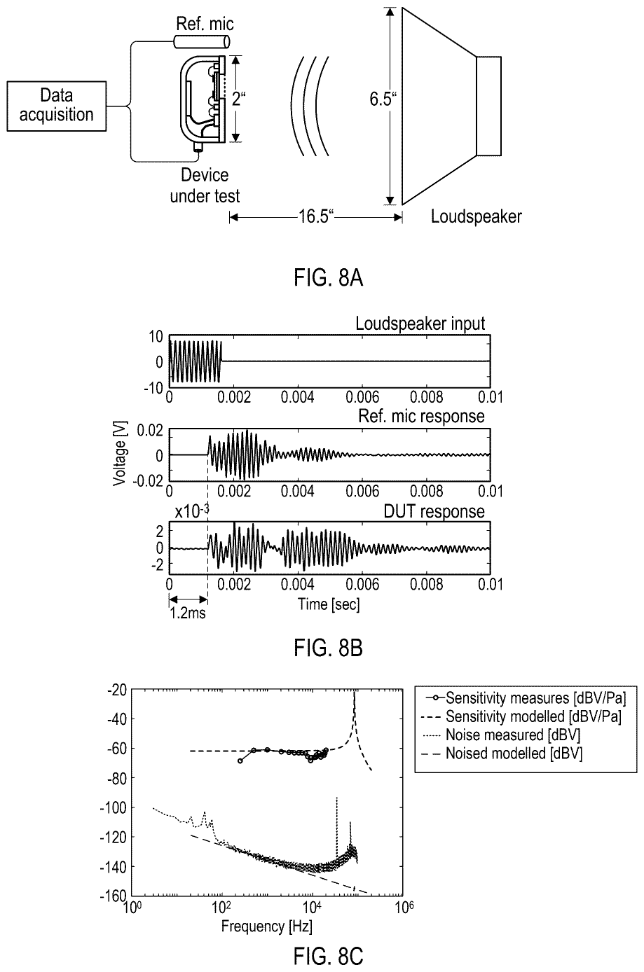

FIGS. 8A-8C illustrate an example of an acoustic measurement of an LN MEMS microphone. In particular, FIG. 8A illustrates an example of an acoustic measurement free field, FIG. 8B illustrates an example of time-of-flight measurements at 7 kHz using tone burst signals, and FIG. 8C illustrates an example of comparison plots between measurement and modeling for sensitivity and noise. A sensitivity of a LN MEMS microphone prototype can be characterized using tone burst signals in free field as illustrated in FIG. 8A. A calibrated reference microphone (ref. mic) and a DUT package (e.g., as described above) can be placed in closed proximity. A coil loudspeaker can be used to generate a tone burst waveform. The diameter of the coil speaker can be much larger than the size of the DUT package allowing the assumption that the reference microphone and the DUT package experience similar acoustic pressure amplitude. FIG. 8B illustrates examples of the loudspeaker input, reference microphone response, and DUT package response. The acoustic receive waveforms of the reference microphone and the DUT package show about 1.2 ms time delay relative to the source input (e.g., loudspeaker input). The computed propagation distance based on this time of flight is 1.2 ms×343 m/s=16.2 inch, and this approximately equals the distance of 16.5 inch noted in FIG. 8A. This agreement confirms that the observed signals are acoustic, free of EMI. Acoustic sensitivity can be obtained using the DUT package peak voltage response divided by peak pressure obtained from the reference microphone. Many such frequencies can be generated to provide the sensitivity measurements illustrated in FIG. 8C. The DUT package can then be placed inside an anechoic test box to observe the LN diaphragm's self noise floor, also illustrated in FIG. 8C.

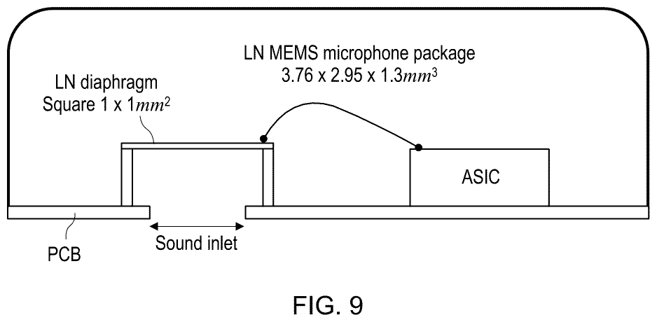

FIG. 9 illustrates an example of one possible design of an LN MEMS microphone, according to some embodiments. In particular, the design illustrated in FIG. 9 and summarized on Table 1 predicts a 73.58 dB(A) signal to noise ratio (SNR) in a MEMS microphone package with dimensions 3.76 mm×2.95 mm×1.3 mm. In comparison, state-of-art commercialized MEMS microphones are approximately 68 dB SNR. As shown in FIG. 9, an example configuration of an LN MEMS microphone can include a Bimorph LN((36° Y LiNbO3)) layer with 2 μm total thickness that can be wafer bonded onto a silicon substrate. A deep silicon etch (DSE) can create the LN diaphragm with 1 mm by 1 mm square shape. A MEMS die housing this diaphragm can be mounted on a PCB substrate with sound inlet. A bonding wire can connect the MEMS die to an ASIC amplifier. A metal lid can cover the MEMS die and ASIC for EMI shielding purposes. Such a diaphragm can obtain 2.8×10⁻¹⁵ m³/Pa acoustical compliance as predicted from FEA.

TABLE 1
A-weighted Noise [dBV(A)] and SNR [dB(A)]

| | |
|---|---|
| Ventilation noise | 9.04 |
| Diaphragm noise | 14.29 |
| Inlet noise | 12.97 |
| Bias resistor noise | 10.14 |
| Flicker noise | 11.80 |
| Dielectric loss noise | 14.76 |
| Total noise | 20.42 |
| SNR | 73.58 |

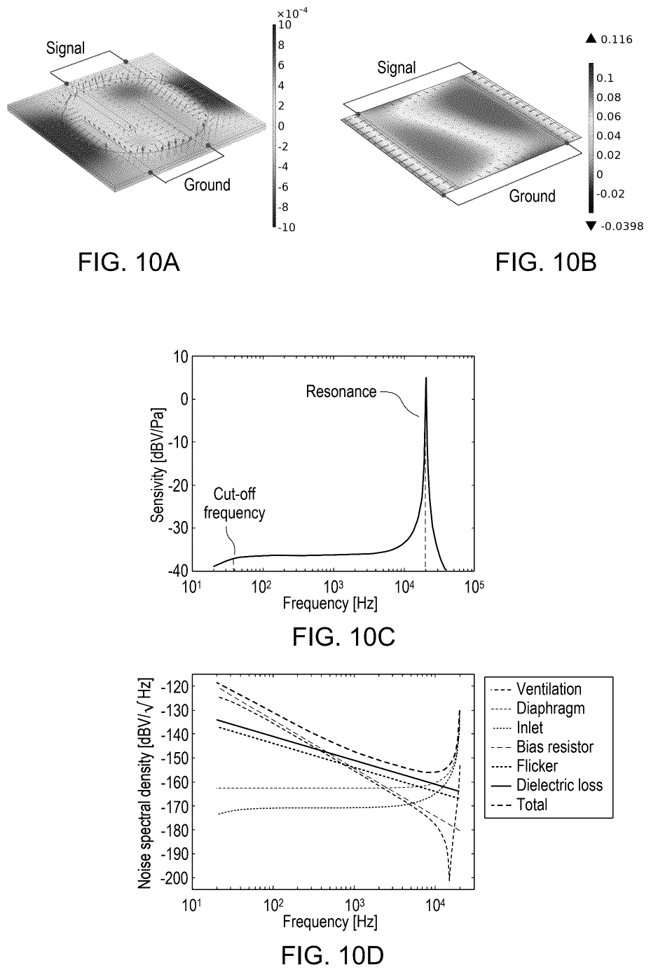

FIGS. 10A-10D illustrate example simulation results of a modeled LN MEMS microphone. In particular, FIG. 10A illustrates a simulated electrical field and electrical potential distribution in response to pressure for a thick diaphragm. Note that while a portion of lateral electrical field lines point from signal to ground electrode, many do not, indicating that a large portion of electrical energy is not transduced by the electrodes. FIG. 10B illustrates simulations of voltage potential and electrical field of an optimized and thinner diaphragm. As illustrated in FIG. 10B, most arrows travel from signal electrodes to ground electrodes, indicating improved energy conversion as compared to the thick diaphragm. FIG. 10C illustrates simulated frequency response and FIG. 10D illustrates simulated noise.

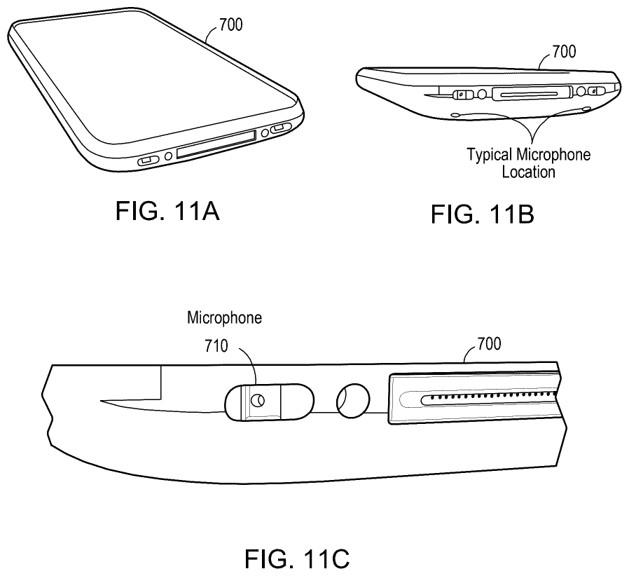

FIGS. 11A-11C illustrate an example of a user equipment device (UE) 700 which can include embodiments of the invention. Note that although UE 700 is illustrated as a cellular phone, the term UE is not limited to cellular phone. The term is intended to refer to any of various types of computer systems devices which are mobile or portable and which performs wireless communications. As shown, UE 700 may include one or more directional microphones 710 which may include embodiments of the invention. In some embodiments, no modification to the UE 700 may be necessary.

Although the embodiments above have been described in considerable detail, numerous variations and modifications will become apparent to those skilled in the art once the above disclosure is fully appreciated. It is intended that the following claims be interpreted to embrace all such variations and modifications.

We claim:

1. A microphone, comprising:
a substrate;
a multilayer structure comprised of at least two layers of lithium niobate crystal and positioned above an inlet of the substrate; and
at least two electrodes mounted on the multilayer structure on a surface opposite a surface facing the inlet; and
wherein the multilayer structure is configured to generate an electric field from deformation, and wherein the electric field generates an electrical signal at the at least two electrodes.

2. The microphone of claim 1,
wherein the multilayer structure comprises a multilayer diaphragm.

3. The microphone of claim 1,
wherein the electric field comprises an in-plane electric field.

4. The microphone of claim 3,
wherein the in-plane electric field is a lateral in-plane electric field.

5. The microphone of claim 1,
wherein the deformation comprises out-of-plane deformation.

6. The microphone of claim 1,
wherein a first layer of the at least two layers of lithium niobate crystal has a first polarization opposite a second polarization of a second layer of the at least two layers of lithium niobate crystal.

7. The microphone of claim 1,
wherein the substrate further comprise a cavity between the multilayer structure and the inlet.

8. The microphone of claim 1,
wherein the deformation is cause by a pressure imbalance between a first surface of the multilayer structure and a second surface of the multilayer structure.

9. A microphone package, comprising:
a first substrate comprising a first inlet;
a microphone die disposed on the substrate over the first inlet, comprising:
a second substrate comprising a second inlet positioned over the first inlet;
a multilayer structure comprised of at least two layers of lithium niobate crystal and positioned above the second inlet of the second substrate; and
at least two electrodes mounted on the multilayer structure on a surface opposite a surface facing the second inlet;
wherein the multilayer structure is configured to generate an electric field from deformation, and wherein the electric field generates an electrical signal at the at least two electrodes; and
an Application Specific Integrated Circuit (ASIC).

10. The microphone package of claim 9, further comprising:
one or more Vertical Interconnect Accesses (VIAs) in one or more of the first substrate or second substrate, wherein the one or more VIAs are configured to provide one or more electrical signals to one or more external surfaces of the microphone package.

11. The microphone package of claim 9,
wherein the multilayer structure comprises a multilayer diaphragm.

12. The microphone package of claim 9,
wherein the electric field comprises an in-plane electric field.

13. The microphone package of claim 12,
wherein the in-plane electric field is a lateral in-plane electric field.

14. The microphone package of claim 9,
wherein the deformation comprises out-of-plane deformation.

15. The microphone package of claim 9,
wherein a first layer of the at least two layers of lithium niobate crystal has a first polarization opposite a second polarization of a second layer of the at least two layers of lithium niobate crystal.

16. The microphone package of claim 9,
wherein the substrate further comprise a cavity between the multilayer structure and the inlet.

17. The microphone package of claim 9,
wherein the deformation is cause by a pressure imbalance between a first surface of the multilayer structure and a second surface of the multilayer structure.

18. A user equipment device (UE), comprising:
at least one microphone;
a memory; and
a processor in communication with the memory and the at least one microphone and configured to digitally processes signals produced from the at least one microphone, and wherein the at least one microphone comprises:
a substrate;
a multilayer structure comprised of at least two layers of lithium niobate crystal and positioned above an inlet of the substrate; and
at least two electrodes mounted on the multilayer structure on a surface opposite a surface facing the inlet; and
wherein the multilayer structure is configured to generate an electric field from deformation, and wherein the electric field generates an electrical signal at the at least two electrodes.

19. The UE of claim 18,
wherein the multilayer structure comprises a multilayer diaphragm, wherein the electric field comprises an in-plane electric field, wherein the in-plane electric field is a lateral in-plane electric field, and wherein the deformation comprises out-of-plane deformation.

20. The UE of claim 18,
wherein a first layer of the at least two layers of lithium niobate crystal has a first polarization opposite a second polarization of a second layer of the at least two layers of lithium niobate crystal.
